(19) United States
(12) Patent Application Publication
(10) Pub. No.: US 2022/0295667 A1
(43) Pub. Date: Sep. 15, 2022

(54) COOLING DEVICE

(71) Applicant: Panasonic Intellectual Property Management Co., Ltd., Osaka (JP)

(72) Inventor: Ayaka BANDO, Osaka (JP)

(73) Assignee: Panasonic Intellectual Property Management Co., Ltd., Osaka (JP)

(21) Appl. No.: 17/688,280

(22) Filed: Mar. 7, 2022

(30) Foreign Application Priority Data
Mar. 10, 2021 (JP) 2021-038401

(51) Int. Cl. H05K 7/20

(52) U.S. Cl. CPC H05K 7/20327; H05K 7/20818; H05K 7/20318; H05K 7/2039; H05K 7/20309

(57) ABSTRACT

A cooling device includes a plurality of heat receiving parts each disposed on one of a plurality of heat generating bodies, and having a refrigerant evaporation space in which a portion of a refrigerant is evaporated in the refrigerant evaporation space by heat of one of the plurality of heat generating bodies, a heat dissipating part condensing the refrigerant evaporated in the plurality of heat receiving parts, a refrigerant supply path through which the refrigerant condensed by the heat dissipating part to transition into a liquid-phase refrigerant flowing toward the plurality of heat receiving parts, and a refrigerant reflux path through which a gas-liquid multiphase flow of the liquid-phase refrigerant and the refrigerant evaporated in the heat receiving parts to transition into a gas-phase refrigerant flowing toward the heat dissipating part.

### BACKGROUND OF THE INVENTION

### Field of the Invention

The present disclosure relates to a cooling device that uses a refrigerant.

### Description of the Related Art

For example, Japanese Laid-Open Patent Publication No. 2018-105525 describes a cooling device that circulates a refrigerant cooling heat generating bodes, without using any pump.

Specifically, the refrigerant is evaporated by heat of the heat generating bodies, the evaporated refrigerant flows toward a heat dissipating part, and the refrigerant is condensed by the heat dissipating part. The condensed refrigerant flows toward the heat generating bodies, and the refrigerant is again evaporated by the heat of the heat generating bodies. The refrigerant is caused to circulate by the phase transition thereof.

The cooling device described in the above '525 publication is configured to cool the plural heat generating bodies. For example, the refrigerant in a liquid phase flows to each of the plural heat generating bodies, and portions of the refrigerant evaporated by the plural heat generating bodies flow through junction pipes to join in one main pipe. The evaporated refrigerant in the main pipe is condensed by the heat dissipating part, and again flows to each of the plural heat generating bodies.

In the case of the cooling device of the above '525 publication, the refrigerant in the junction pipe located closest to the heat dissipating part may however be unable to flow into the main pipe and may flow backward toward the heat generating body. The pressure at a point in the main pipe becomes higher as the point becomes closer to the heat dissipating part, and it is difficult for the refrigerant in the junction pipe that is located closest to the heat dissipating part to flow into the main pipe. When the pressure difference is small between the pressure in the vicinity of the junction point of the junction pipe located closest to the heat dissipating part and the main pipe, and the pressure in the junction pipe, a backward flow of the refrigerant occurs in the junction pipe. As a result, the cooling efficiency for the heat generating body that corresponds to the junction pipe may be degraded.

### SUMMARY OF THE INVENTION

An object of the present disclosure is to suppress a backward flow of a refrigerant in a cooling device whose portions of the refrigerant evaporated by heat of plural heat generating bodies join.

To achieve the above object, according to one aspect of the present disclosure, a cooling device comprises: a plurality of heat receiving parts that each are disposed on one of a plurality of heat generating bodies, the plurality of heat receiving parts each having a refrigerant evaporation space, a portion of a refrigerant being evaporated in the refrigerant evaporation space by heat of one of the plurality of heat generating bodies; a heat dissipating part that condenses the refrigerant evaporated in the plurality of heat receiving parts; a refrigerant supply path that connects the heat dissipating part and the plurality of heat receiving parts to each other, the refrigerant condensed by the heat dissipating part to transition into a liquid-phase refrigerant flowing in the refrigerant supply path toward the plurality of heat receiving parts; and a refrigerant reflux path that connects the plurality of heat receiving parts and the heat dissipating part to each other, a gas-liquid multiphase flow of the liquid-phase refrigerant and the refrigerant evaporated in the heat receiving parts to transition into a gas-phase refrigerant flowing in the refrigerant reflux path toward the heat dissipating part. The refrigerant reflux path includes a main pipe that extends toward the heat dissipating part and a plurality of junction pipes that each connect the main pipe and one of the plurality of heat receiving parts to each other. The main pipe is fabricated such that junction points of the plurality of junction pipes with the main pipe are different in a position of each of the junction points in an extensional direction of the main pipe and such that a flow path cross-sectional area at a position of the main pipe becomes larger as the position becomes closer to the heat dissipating part.

According to the present disclosure, any backward flow of the refrigerant can be suppressed in a cooling device whose portions of refrigerant evaporated by plural heat generating bodies join.

### BRIEF DESCRIPTION OF THE DRAWINGS

FIG. 1 is a schematic diagram of a server;

FIG. 2 is a diagram depicting a board of the server that mounts thereon a cooling device according to one embodiment of the present disclosure;

FIG. 3 is a cross-sectional diagram of the cooling device;

FIG. 4 is a schematic diagram depicting a refrigerant reflux path and a pressure gradient in a main pipe thereof in the cooling device according to the embodiment;

FIG. 5 is a schematic diagram depicting a refrigerant reflux path and a pressure gradient in a main pipe thereof in a cooling device according to a comparative example; and

FIG. 6 is a schematic diagram of a refrigerant reflux path in a cooling device according to another embodiment.

### DESCRIPTION OF THE PREFERRED EMBODIMENTS

An embodiment will be described in detail below with reference to the drawings when necessary. Description more detailed than necessary may not be made. For example, items already well known may not be described in detail and substantially identical configurations may not redundantly be described. These are to avoid making the following description unnecessarily redundant and to facilitate understanding of those skilled in the art.

The inventors will provide the accompanying drawings and the following description for those skilled in the art to fully understand the present disclosure, and do not intend to limit the subject described in claims by the above.

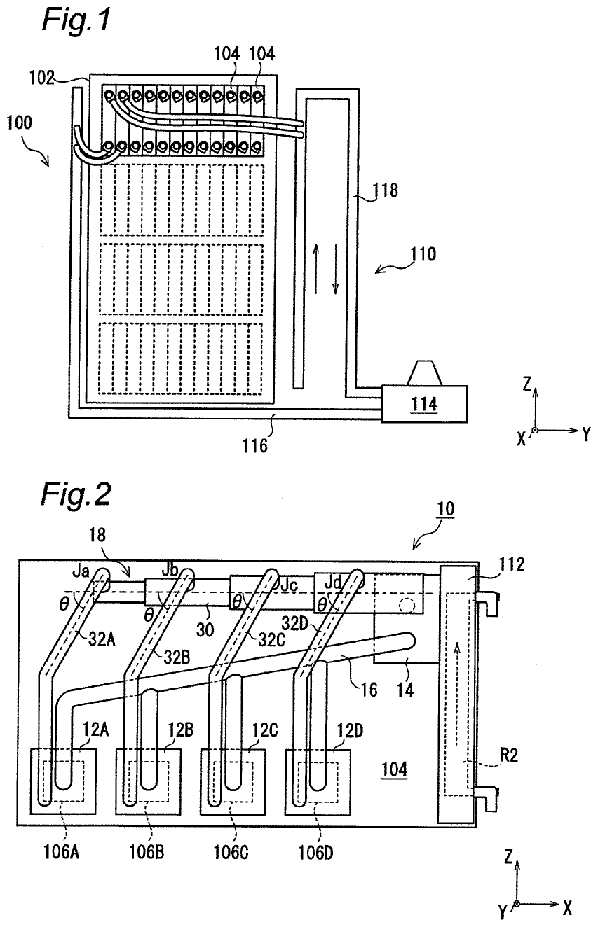

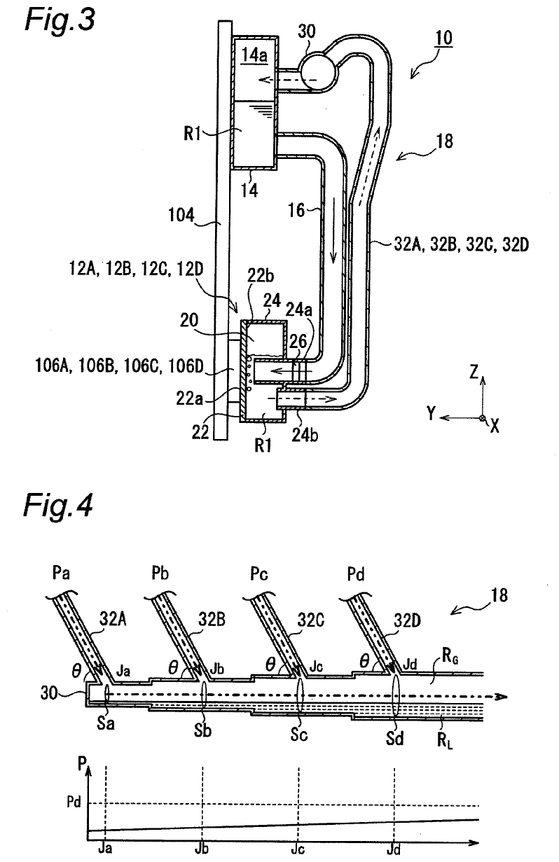

FIG. 1 is a schematic diagram of a server. FIG. 2 is a diagram depicting a board of the server that mounts thereon a cooling device according to one embodiment of the present disclosure. FIG. 3 is a cross-sectional diagram of the cooling device.

X-Y-Z Cartesian coordinate systems depicted in the drawings are to facilitate understanding of the embodiment of the present disclosure, and do not limit the embodiment. The X-axis direction indicates the depth direction, the Y-axis direction indicates the width direction, and the Z-axis direction indicates the height direction.

As depicted in FIG. 1, the server 100 is a what-is-called rack-mountable server and includes a rack 102 and plural boards 104 disposed in the rack 102.

As depicted in FIG. 2, a board 104 has plural heat generating bodies 106A to 106D mounded thereon such as a CPU and a memory. The board 104 has a cooling device 10 according to this embodiment mounted thereon to cool the heat generating bodies 106A to 106D.

The cooling device 10 includes plural heat receiving parts 12A to 12D that respectively cool the plural heat generating bodies 106A to 106D using a refrigerant R1, a heat dissipating part 14 that condenses the refrigerant R1, a refrigerant supply path 16 that connects the heat dissipating part 14 and the plural heat receiving parts 12A to 12D to each other and through which the refrigerant R1 flows toward the heat receiving parts 12A to 12D, and a refrigerant reflux path 18 that connects the plural heat receiving parts 12A to 12D and the heat dissipating part 14 to each other and through which the refrigerant R1 flows toward the heat dissipating part 14. The refrigerant R1 is, for example, water or a fluorinated refrigerant.

As depicted in FIG. 2, the heat receiving part 12A is disposed on the heat generating body 106A, the heat receiving part 12B is disposed on the heat generating body 106B, the heat receiving part 12C is disposed on the heat generating body 106C, and the heat receiving part 12D is disposed on the heat generating body 106D. The configuration of each of the heat receiving parts 12A to 12D is substantially identical to each other.

As depicted in FIG. 3, each of the plural heat receiving parts 12A to 12D includes a refrigerant evaporation space 20 for the refrigerant R1 to be evaporated therein.

For example, in the case of this embodiment, each of the plural heat receiving parts 12A to 12D includes a heat conducting plate 22 that abuts the corresponding one of the heat generating bodies 106A to 106D, and a covering member 24 that defines the refrigerant evaporation space 20 by covering the heat conducting plate 22.

The heat conducting plate 22 of each of the heat receiving parts 12A to 12D is made from a material having a high heat conductivity such as, for example, copper. The heat conducting plate 22 includes a heat absorbing face 22a that abuts the corresponding one of the heat generating bodies 106A to 106D to absorb heat therefrom, and a heat dissipating face 22b located on the side opposite to the heat absorbing face 22a. The heat dissipating face 22b contacts the refrigerant R1 present in the refrigerant evaporation space 20 and evaporates the refrigerant R1 using the heat absorbed from the corresponding one of the heat generating bodies 106A to 106D.

The covering member 24 of each of the heat receiving parts 12A to 12D covers the heat dissipating face 22b of the heat conducting plate 22 and thereby demarcates the refrigerant evaporation space 20 in cooperation with the heat conducting plate 22. The covering member 24 is made from a highly pressure-resistant material such as, for example, a metal material.

The covering member 24 is provided with a refrigerant supply connection part 24a that is connected to the refrigerant supply path 16, and a refrigerant discharge connection part 24b that is connected to the refrigerant reflux path 18. The refrigerant supply connection part 24a causes the refrigerant supply path 16 and the refrigerant evaporation space 20 to communicate with each other. The refrigerant discharge connection part 24b causes the refrigerant reflux path 18 and the refrigerant evaporation space 20 to communicate with each other. In the case of this embodiment, the refrigerant discharge connection part 24b is disposed at a position that is low compared to the position of the refrigerant supply connection part 24a.

The refrigerant supply connection part 24a of the covering member 24 is provided with a check valve 26. The check valve 26 is configured to cause the refrigerant R1 flowing from the refrigerant supply path 16 toward the refrigerant evaporation space 20 to pass therethrough and to however block the refrigerant R1 flowing backward from the refrigerant evaporation space 20 toward the refrigerant supply path 16.

The heat dissipating part 14 of the cooling device 10 condenses the refrigerant R1 evaporated in each of the heat receiving parts 12A to 12D. The heat dissipating part 14 is a refrigerant tank made from, for example, a material having a high heat dissipating property such as, for example, copper, and includes a refrigerant condensation space 14a that has the refrigerant R1 condensed and stored therein.

In the case of this embodiment, to facilitate collection of the refrigerant R1 evaporated by each of the heat receiving parts 12A to 12D, the heat dissipating part 14 is disposed at a position that is high compared to the positions of the heat receiving parts 12A to 12D.

In the case of this embodiment, the heat dissipating part 14 is cooled by a liquid-cooling unit 110 depicted in FIG. 1. As depicted in FIG. 2, the liquid-cooling unit 110 is disposed on each of the plural boards 104, and includes a heat sink block 112 that absorbs heat from the heat dissipating part 14, and a pump 114 that sends out a refrigerant R2 into the heat sink block 112. The liquid-cooling unit 110 includes a supply manifold 116 that supplies the refrigerant R2 from the pump 114 to the heat sink block 112 on each of the plural boards 104, and a collection manifold 118 that collects the refrigerant R2 from the heat sink block 112 on each of the plural boards 104 to return the collected refrigerant R2 to the pump 114. The heat dissipating part 14 of the cooling device is cooled by the above liquid-cooling unit 110.

As depicted in FIG. 2, the refrigerant supply path 16 of the cooling device 10 is, for example, a branched pipe that is connected to the heat dissipating part 14 and each of the plural heat receiving parts 12A to 12D to each other. In the case of this embodiment, the refrigerant supply path 16 has branches at plural points to be connected to the plural heat receiving parts 12A to 12D. The refrigerant R1 condensed by the heat dissipating part 14, that is, the refrigerant R1 in a liquid phase flows in the refrigerant supply path 16 from the heat dissipating part 14 toward each of the plural heat receiving parts 12A to 12D. In the case of this embodiment, because the heat dissipating part 14 is disposed at the position that is high compared to the position of each of the heat receiving parts 12A to 12D, the liquid-phase refrigerant R1 flows toward the heat receiving parts 12A to 12D by gravity.

As depicted in FIG. 2, the refrigerant reflux path 18 of the cooling device 10 connects each of the plural heat receiving parts 12A to 12D and the heat dissipating part 14 to each other. The refrigerant R1 evaporated in each of the plural heat receiving parts 12A to 12D flows in the refrigerant reflux path 18 from the plural heat receiving parts 12A to 12D toward the heat dissipating part 14.

The refrigerant reflux path 18 includes a main pipe 30 that extends toward the heat dissipating part 14, and junction pipes 32A to 32D that connect the main pipe 30 and the plural heat receiving parts 12A to 12D to each other. Junction points Ja to Jd of the plural junction pipes 32A to 32D with the main pipe 30 are different in the position thereof in the extensional direction of the main pipe 30 (the X-axis direction). In the case of this embodiment, the main pipe 30 extends in the horizontal direction.

As depicted in FIG. 3, according to the above cooling device 10, when the plural heat generating bodies 106A to 106D generate heat, a portion of the refrigerant R1 in the refrigerant evaporation space 20 of each of the heat receiving parts 12A to 12D is evaporated (transitions into a gas phase thereof). The pressure in the refrigerant evaporation space 20 is thereby increased and the gas-phase refrigerant R1 enters into the refrigerant reflux path 18 through the refrigerant discharge connection part 24b. At this time, the gas-phase refrigerant R1 accompanied by another portion not evaporated (in the liquid phase) of the refrigerant R1 enters into the refrigerant reflux path 18. A gas-liquid multiphase flow of the gas-phase refrigerant R1 and the liquid-phase refrigerant R1 flows in the refrigerant reflux path 18 toward the heat dissipating part 14.

When the gas-liquid multiphase flow of the refrigerant R1 arrives in the refrigerant condensation space 14a of the heat dissipating part 14, the gas-phase refrigerant R1 is condensed into the liquid phase thereof. The liquid-phase refrigerant R1 is thereby stored in the refrigerant condensation space 14a. The liquid-phase refrigerant R1 in the refrigerant condensation space 14a is supplied to the refrigerant evaporation space 20 of each of the plural heat receiving parts 12A to 12D through the refrigerant supply path 16.

The refrigerant R1 can circulate by the above phase change of the refrigerant R1 without using any pump or the like, and can thereby continuously cool the plural heat generating bodies 106A to 106D.

In the case where the heat generating bodies 106A to 106D generates no heat, the inside of the refrigerant evaporation space 20 of each of each of the heat receiving parts 12A to 12D is filled with the liquid-phase refrigerant R1.

The main pipe 30 of the refrigerant reflux path 18 of this embodiment is formed such that the flow path cross-sectional area at a position of the main pipe 30 becomes larger in a stepwise manner as the position becomes closer to the heat dissipating part 14. The flow path cross-sectional area referred to herein refers to the cross-sectional area of the inside space taken perpendicularly to the flow direction of the refrigerant flowing in the inside space of the main pipe 30.

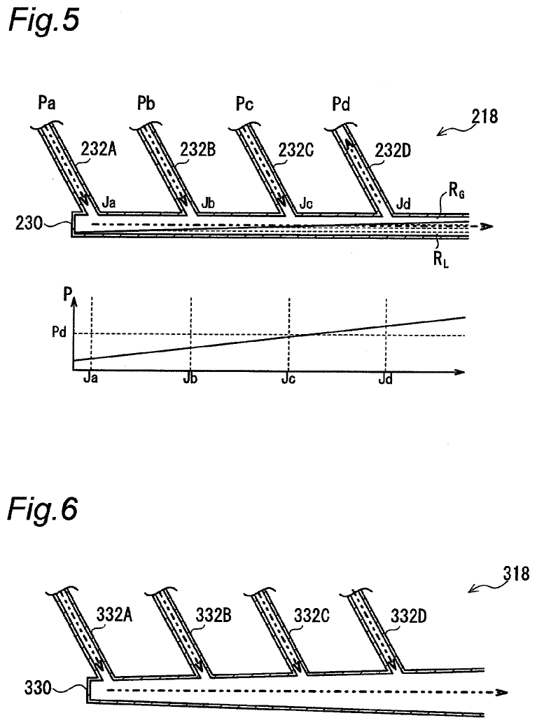

The reason why the main pipe 30 of the refrigerant reflux path 18 is formed such that the flow path cross-sectional area at a position of the main pipe 30 becomes larger in a stepwise manner as the position becomes closer to the heat dissipating part 14 as above is that the gas-liquid multiphase flow of the refrigerant R1 flows in the refrigerant reflux path 18 as above. This will be described with reference to FIGS. 4 and 5.

FIG. 4 is a schematic diagram depicting the refrigerant reflux path and the pressure gradient in the main pipe thereof in the cooling device according to the embodiment. FIG. 5 is a schematic diagram depicting a refrigerant reflux path and the pressure gradient in a main pipe thereof in a cooling device according to a comparative example.

As depicted in FIG. 4, the main pipe 30 of the refrigerant reflux path 18 in the cooling device 10 according to this embodiment is formed such that the flow path cross-sectional area at a position of the main pipe 30 becomes larger as the position becomes closer to the heat dissipating part 14 (as the position moves to the right side in FIG. 4). For example, flow path cross-sectional areas Sa to Sd at the junction points Ja to Jd of the junction pipes 32A to 32D and the main pipe 30 become larger in sequence as the junction point becomes closer to the heat dissipating part 14. As to the flow path cross-sectional areas of two junction points adjacent to each other in the extensional direction of the main pipe 30 (such as, for example, the junction points Jb and Jc), the flow path cross-sectional area at the junction point close to the heat dissipating part 14 is large compared to the flow path cross-sectional area at the junction point far from the heat dissipating part 14.

On the other hand, as depicted in FIG. 5, the main pipe 230 of the refrigerant reflux path 218 in the cooling device according to the comparative example has a constant flow path cross-sectional area.

As depicted in FIG. 5, in the case where the flow path cross-sectional area of the main pipe 230 of the refrigerant reflux path 218 is constant, a backward flow(s) of the refrigerant may occur in, for example, some of plural junction pipes 232A to 232D. FIG. 5 depicts the state where a backward flow (a flow toward the heat receiving part) occurs in the junction pipe 232D located closest to a heat dissipating part, that is, positioned most downstream in the flow direction of the refrigerant flowing in the main pipe 230. The reason why the backward flow occurs in the junction pipe 232D is that a pressure P in the vicinity of the junction point Jd of the junction pipe 232D and the main pipe 230 is high compared to a pressure Pd in the junction pipe 232D.

Describing in detail, a gas-liquid multiphase flow flows from each of the junction pipes 232A to 232C on the side upstream to the junction pipe 232D into the main pipe 230. Liquid-phase refrigerants R_{L} join in succession and the amount thereof becomes larger as the refrigerants R_{L} move more downstream (become closer to the heat dissipating part).

The volume occupied by the liquid-phase refrigerants R_{L} is increased as the liquid-phase refrigerants R_{L} move more downstream due to the fact that the amount of the liquid-phase refrigerants R_{L} becomes larger as the liquid-phase refrigerants R_{L} move more downstream. On the other hand, because the flow path cross-sectional area of the main pipe 230 is constant, the volume occupied by a gas-phase refrigerant R_{G} is reduced as the gas-phase refrigerant R_{G} moves more downstream. The pressure of the gas-phase refrigerant R_{G} at a point, that is, a pressure P at the point in the main pipe 230 thereby becomes higher as the position moves more downstream. As a result, as depicted in FIG. 5, the pressure gradient of the pressure P in the main pipe 230 becomes steep, and the refrigerant in the junction pipe 232D located most downstream cannot flow into the main pipe 230. A backward flow occurs for the refrigerant in the main pipe 230 to intrude into the junction pipe 232D. When the backward flow occurs, the cooling efficiency is degraded for the heat generating body on which the heat receiving part adjacent to the junction pipe 232D having the backward flow occurring therein is disposed.

To suppress the occurrence of the steep pressure gradient that causes the backward flow, as depicted in FIG. 4, in the case of this embodiment, the main pipe 30 of the refrigerant reflux path 18 is formed such that the flow path cross-sectional area thereof at a position becomes larger as the position becomes closer to the heat dissipating part 14 (to the right side in FIG. 4). The volume occupied by the gas-phase refrigerant R_{G} is thereby not reduced even when the volume occupied by the liquid-phase refrigerants R_{L} at a position becomes larger as the position moves downstream more due to the fact that the amount of the liquid-phase refrigerants R_{L} at a position becomes larger as the position moves downstream more (as the position becomes closer to the heat dissipating part 14). On the contrary, in the case of this embodiment, the volume occupied by the gas-phase refrigerant R_{G} at a position becomes larger as the position moves downstream more. The pressure gradient of the pressure P in the main pipe 30 is thereby made mild, and the pressure P in the vicinity of the junction point Jd of the junction pipe 32D located most downstream and the main pipe 30 thereby becomes low compared to the pressure Pd in the junction pipe 32D. As a result, the refrigerant in the junction pipe 32D can flow into the main pipe 30 and the backward flow of the refrigerant can be suppressed.

The main pipe 30 having the above shape is determined as follows. For example, The flow path cross-sectional area Sd at the junction point Jd of the junction pipe 32D located most downstream and the main pipe 30 is determined to be a size with which, even when pressures Pa to Pc respectively in the junction pipes 32A to 32D on the side more upstream than the junction pipe 32D are each a saturated vapor pressure, the refrigerant in the junction pipe 32D can flow into the main pipe 30.

Even in the case where the flow path cross-sectional area of the main pipe is constant, the backward flow of the refrigerant in the junction pipe can be suppressed when the flow path cross-sectional area of the main pipe is set to be sufficiently large. In this case, however, a problem arises that the upstream-side portion of the main pipe is uselessly large and the disposition space of the refrigerant reflux path, that is, the disposition space of the cooling device is thereby expanded. On the other hand, the disposition space of the refrigerant reflux path 18 can be reduced by forming the main pipe 30 such that the flow path cross-sectional area at a position of the main pipe 30 becomes larger as the position becomes closer to the heat dissipating part 14 as depicted in FIGS. 2 and 4.

It is preferred that, in the case where the distance is short between two junction points adjacent to each other in the extensional direction of the main pipe 30 (such as, for example, the junction points Jb and Jc), the flow path cross-sectional area at the junction point located close to the heat dissipating part 14 be set to be large compared to the flow path cross-sectional area at the junction point located far from the heat dissipating part 14 as depicted in FIGS. 2 and 4. The refrigerant in the junction pipe located on the side close to the heat dissipating part 14 is thereby facilitated to flow into the main pipe 30 in the case where the pressures in the junction pipes connected to the two junction points close to each other are approximately equal to each other. In the case where the distance is sufficiently long between two junction points adjacent to each other, the flow path cross-sectional areas thereof may be equal to each other. This is because a pressure drop occurs in the course of flowing of the refrigerant from the junction point located far from the heat dissipating part 14, to the junction point located close thereto.

It is preferred that, as depicted in FIGS. 2 and 4, to suppress occurrence of any backward flow in each of the junction pipes 32A to 32D, each of the junction pipes 32A to 32D be connected to the main pipe 30 at an acute angle θ relative to the extensional direction of the main pipe 30 (the X-axis direction) by extending toward the front of the main pipe 30 (the side of the heat dissipating part 14) approaching the main pipe 30.

It is preferred that, as depicted in FIG. 3, the junction pipes 32A to 32D each extend downward from the above of the main pipe 30 to be connected to the main pipe 30. The refrigerant R1 of the gas-liquid multiphase flow flows in the main pipe 30 as above. The gas-phase refrigerant R1 and the liquid-phase refrigerant R1 may be separated one on the other depending on the state of the heat generation of each of the heat generating bodies 106A to 106D. The liquid-phase refrigerant R1 may flow along the bottom of the main pipe 30. In this case, when the junction pipes 32A to 32D are connected to the main pipe 30 from underneath, the liquid-phase refrigerant R1 intrudes into the junction pipe connected to the heat receiving part that absorbs heat from a heat generating body generating a small amount of heat. As a result, the cooling efficiency of the heat generating body is degraded. It is therefore preferred that the junction pipes 32A to 32D extend downward from the above of the main pipe 30 to be connected to the main pipe 30 in the case where the amount of the generated heat of the heat generating body may be zero or very small.

According to this embodiment as above, in the cooling device whose portions of the refrigerant evaporated by the heat of the plural heat generating bodies join, any backward flow of the refrigerant can be suppressed.

The present disclosure has been described as above with reference to the above embodiment and embodiments of the present discloser is however not limited to the above embodiment.

For example, in the case of the above embodiment, as depicted in FIGS. 1 and 2, the heat dissipating part 14 is cooled by the liquid-cooling unit 110. The refrigerant R1 in the heat dissipating part 14 is thereby condensed. Embodiments of the present disclosure is however not limited to the above. For example, the heat dissipating part 14 may be air-cooled using a fan or the like.

In the case of the above embodiment, as depicted in FIGS. 2 and 4, the main pipe 30 of the refrigerant reflux path 18 is formed such that the flow path cross-sectional area at a position of the main pipe 30 becomes larger in a stepwise manner as the position becomes closer to the heat dissipating part 14. Embodiments of the present disclosure is however not limited to the above.

FIG. 6 is a schematic diagram of a refrigerant reflux path in a cooling device according to another embodiment.

In the refrigerant reflux path 318 depicted in FIG. 6, a main pipe 330 to which plural junction pipes 332A to 332D are connected is formed such that the flow path cross-sectional area at a position of the main pipe 30 becomes linearly larger as the position becomes closer to the heat dissipating part 14 (as the position moves to the right side in FIG. 6). Even the main pipe 330 can suppress occurrence of any backward flow in the junction pipes in the same manner as the main pipe 30 of the above embodiment does.

In the case of the above embodiment, the cooling device is used in the server. Embodiments of the present disclosure is however not limited to the above. The cooling device is usable for cooling plural heat generating bodies each generating an amount of heat that evaporates the refrigerant.

In a broad sense, one embodiment according to the present disclosure is a cooling device: that includes plural heat receiving parts that each are disposed on one of plural heat generating bodies and that each include a refrigerant evaporation space in which a portion of a refrigerant is evaporated by heat of the heat generating body, a heat dissipating part that condenses the refrigerant evaporated in the plural heat receiving parts, a refrigerant supply path that connects the heat-dissipating part and the plural heat receiving parts to each other and in which the refrigerant condensed by the heat dissipating part to transition into a liquid-phase refrigerant flows toward the plural heat receiving parts, and a refrigerant reflux path that connects the plural heat receiving parts and the heat dissipating part to each other and in which a gas-liquid multiphase flow of the refrigerant evaporated in the heat receiving parts to transition into a gas-phase refrigerant and the liquid-phase refrigerant flows toward the heat dissipating part; and in which the refrigerant reflux path includes a main pipe that extends toward the heat dissipating part, and plural junction pipes that each connect the main pipe and one of the plural heat receiving parts to each other, junction points of the plural junction pipes with the main pipe are different in the position thereof in the extensional direction of the main pipe, and the flow path cross-sectional area at a position of the main pipe becomes larger as the position becomes closer to the heat dissipating part.

As above, the embodiment has been described as an exemplification of the technique in the present disclosure. The accompanying drawings and the detailed description have been presented for the above. The constituent elements depicted in accompanying drawings and/or described in the detailed description may therefore include not only the constituent elements essential to solve the problem but also the constituent elements unessential to solve the problem to exemplify the technique. The unessential constituent elements should not readily be recognized as essential based on the fact that the unessential constituent elements are depicted in the accompanying drawings and/or described in the detailed description.

The above embodiment is to exemplify the technique in the present disclosure, and various changes, substitutions, additions, omissions, and the like can therefore be made in the scope of the claims or a scope equivalent to that of the claims.

The present disclosure is applicable to a cooling device that cools plural heat generating bodies using a refrigerant.

What is claimed is:

1. A cooling device comprising:
a plurality of heat receiving parts that each are disposed on one of a plurality of heat generating bodies, the plurality of heat receiving parts each having a refrigerant evaporation space, a portion of a refrigerant being evaporated in the refrigerant evaporation space by heat of one of the plurality of heat generating bodies;
a heat dissipating part that condenses the refrigerant evaporated in the plurality of heat receiving parts;
a refrigerant supply path that connects the heat dissipating part and the plurality of heat receiving parts to each other, the refrigerant condensed by the heat dissipating part to transition into a liquid-phase refrigerant flowing in the refrigerant supply path toward the plurality of heat receiving parts; and
a refrigerant reflux path that connects the plurality of heat receiving parts and the heat dissipating part to each other, a gas-liquid multiphase flow of the liquid-phase refrigerant and the refrigerant evaporated in the heat receiving parts to transition into a gas-phase refrigerant flowing in the refrigerant reflux path toward the heat dissipating part, wherein
the refrigerant reflux path includes a main pipe that extends toward the heat dissipating part and a plurality of junction pipes that each connect the main pipe and one of the plurality of heat receiving parts to each other, wherein
junction points of the plurality of junction pipes with the main pipe are different in a position in an extensional direction of the main pipe, and wherein
a flow path cross-sectional area at a position of the main pipe becomes larger as the position becomes closer to the heat dissipating part.

2. The cooling device according to claim 1, wherein
the flow path cross-sectional area at a position of the main pipe of the refrigerant reflux path becomes larger in a stepwise manner as the position becomes closer to the heat dissipating part.

3. The cooling device according to claim 1, wherein
the flow path cross-sectional area at a position of the main pipe of the refrigerant reflux path becomes linearly larger as the position becomes closer to the heat dissipating part.

4. The cooling device according to claim 1, wherein
as to flow path cross-sectional areas of the main pipe at two of the junction points adjacent to each other in the extensional direction, the flow path cross-sectional area at the junction point located close to the heat dissipating part is large compared to the flow path cross-sectional area at the junction point located far from the heat dissipating part 14.

5. The cooling device according to claim 1, wherein
the plurality of junction pipes each extend downward from above of the main pipe to be connected to the main pipe.

6. The cooling device according to claim 1, wherein
each of the plurality of heat receiving parts comprises:
a heat conducting plate that includes a heat absorbing face abutting one of the plurality of heat generating bodies, and a heat dissipating face located on a side opposite to a side of the heat absorbing face;
a covering member that defines the refrigerant evaporation space by covering the heat dissipating face of the heat conducting plate;
a refrigerant supply connection part that is disposed on the covering member, the refrigerant supply connection part being connected to the refrigerant supply path; and
a refrigerant discharge connection part that is disposed on the covering member, the refrigerant discharge connection part being connected to the junction pipe; and
a check valve that is disposed on the refrigerant supply connection part, the check valve blocking a backward flow of the refrigerant from the refrigerant evaporation space to the refrigerant supply path.
